(19) United States
(12) Patent Application Publication
(10) Pub. No.: US 2025/0359198 A1
(43) Pub. Date: Nov. 20, 2025

(54) Semiconductor structure including silicon-on-insulator substrate and its manufacturing method

(71) Applicant: UNITED MICROELECTRONICS CORP., Hsin-chu City (TW)

(72) Inventors: Abhishek Attri, Ambala City (IN); Rudy Octavius Sihombing, Batam (ID); Su Xing, Singapore (SG)

(73) Assignee: UNITED MICROELECTRONICS CORP., Hsin-chu City (TW)

(21) Appl. No.: 18/744,675

(22) Filed: Jun. 16, 2024

(30) Foreign Application Priority Data
May 16, 2024 (TW) 113118232

(51) Int. Cl. H01L 29/06; H01L 21/02; H01L 21/304; H01L 21/762

(52) U.S. Cl. CPC H10D 62/102; H01L 21/02694; H01L 21/304; H01L 21/76283

(57) ABSTRACT

The present invention provides a semiconductor structure comprising a silicon-on-insulator (SOI) substrate, including a material layer defined with a central region and two edge regions, wherein the central region is situated between the two edge regions. An oxide layer and a silicon layer are stacked from bottom to top on the material layer, wherein the thickness of the silicon layer in the central region is greater than the thickness of the silicon layer in the two edge regions. The semiconductor structure of the present invention has advantages such as reducing interface capacitance, lowering bulk resistance, mitigating gate-induced drain leakage (GIDL) effects, possessing high off-state capacitance, reducing static power consumption, and enhancing device quality.

### BACKGROUND OF THE INVENTION

### 1. Field of the Invention

The present invention pertains to the field of semiconductors, specifically addressing a semiconductor structure with a silicon-on-insulator (SOI) substrate of a special shape and its fabrication method. It offers advantages such as reduced interface capacitance, decreased bulk resistance, mitigated gate-induced drain leakage (GIDL) effects, high off-state capacitance, lowered static power consumption, and improved device quality.

### 2. Description of the Prior Art

Silicon-on-insulator (SOI) technology finds wide applications in the semiconductor industry. Its key feature involves placing an insulating layer (typically silicon oxide) between the silicon substrate and the active layer of a chip, thereby enhancing the electrical properties and performance of the chip.

SOI technology brings several process advantages. Firstly, conventional semiconductor devices are built on single-crystal silicon substrates, whereas SOI technology allows devices to be built on an insulating layer, effectively eliminating the negative impact of impurities on device performance. This enables faster operation, lower power consumption, and increased radiation and noise immunity, which are crucial for applications with strict reliability requirements.

Secondly, SOI technology provides better device isolation. With the active layer surrounded by an insulating layer, crosstalk between devices is significantly reduced, leading to improved integration and performance of integrated circuits. Additionally, SOI technology reduces capacitive coupling between devices, further enhancing device operation speed and power efficiency.

However, SOI technology also faces challenges and drawbacks. Firstly, manufacturing SOI wafers typically incurs higher costs due to the additional processing steps required to add the insulating layer. Secondly, the insulating layer in SOI technology may impose some limitations on device design; for instance, in certain high-power applications, the insulating layer may affect thermal dissipation, restricting the device's power density.

In summary, SOI technology, as an important semiconductor manufacturing process, offers significant advantages including excellent electrical performance and device characteristics. However, challenges such as process costs and limitations in device design still need to be addressed.

### SUMMARY OF THE INVENTION

The present invention provides a semiconductor structure comprising a silicon-on-insulator (SOI) substrate with a special shape, wherein a material layer defines a central region and two edge regions, with the central region situated between the two edge regions. An oxide layer and a silicon layer are stacked from bottom to top on the material layer, with the thickness of the silicon layer in the central region greater than that in the edge regions.

Additionally, the invention provides a method for fabricating a semiconductor structure comprising an SOI substrate. The method involves providing a material layer defining a central region and two edge regions, forming an oxide layer and a silicon layer stacked on the material layer, depositing a mask layer on the silicon layer within the central region, and performing oxygen ion implantation to penetrate through the silicon layer.

Another fabrication method includes providing a material layer and a silicon layer, both defining a central region and two edge regions, with the central region positioned between the edge regions. An oxide layer is formed on the material layer, and a first mask layer is formed on the silicon layer within the central region. Subsequent steps involve etching the oxide layer to create a recessed portion in the central region and etching the silicon layer to create a protruding portion in the central region, followed by flipping the silicon layer to allow the recessed portion on the oxide layer to interlock with the protruding portion on the silicon layer.

The invention's semiconductor structure features a silicon-on-insulator substrate with a special shape, wherein the oxide layer in the central region has a recessed portion, resulting in a greater thickness of the silicon layer in the central portion compared to the edge regions. This configuration offers several advantages: 1. Reduced interface capacitance; 2. Decreased bulk resistance; 3. Mitigated gate-induced drain leakage (GIDL) effects; 4. Compatibility with existing technologies without requiring additional masks; 5. High off-state capacitance and reduced static power consumption; and 6. Enhanced device quality.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

In order to make the following easier to understand, readers can refer to the drawings and their detailed descriptions at the same time when reading the present invention. Through the specific embodiments in the present specification and referring to the corresponding drawings, the specific embodiments of the present invention will be explained in detail, and the working principle of the specific embodiments of the present invention will be expounded. In addition, for the sake of clarity, the features in the drawings may not be drawn to the actual scale, so the dimensions of some features in some drawings may be deliberately enlarged or reduced.

FIG. 1 illustrates a cross-sectional schematic diagram of a semiconductor structure with a silicon-on-insulator (SOI) substrate according to an embodiment of the present invention.

FIG. 2 depicts a cross-sectional schematic diagram of a semiconductor structure with an SOI substrate according to another embodiment of the present invention.

FIGS. 3, FIGS. 4 and FIGS. 5 illustrate cross-sectional schematic diagrams of a process flow for fabricating a semiconductor structure with an SOI substrate according to an embodiment of the present invention.

FIGS. 6, FIGS. 7, FIGS. 8, FIGS. 9, FIGS. 10 and FIGS. 11 depict cross-sectional schematic diagrams of a process flow for fabricating a semiconductor structure with an SOI substrate according to another embodiment of the present invention.

### DETAILED DESCRIPTION

To provide a better understanding of the present invention to users skilled in the technology of the present invention, preferred embodiments are detailed as follows. The preferred embodiments of the present invention are illustrated in the accompanying drawings with numbered elements to clarify the contents and the effects to be achieved.

Please note that the figures are only for illustration and the figures may not be to scale. The scale may be further modified according to different design considerations. When referring to the words “up” or “down” that describe the relationship between components in the text, it is well known in the art and should be clearly understood that these words refer to relative positions that can be inverted to obtain a similar structure, and these structures should therefore not be precluded from the scope of the claims in the present invention.

Although the present invention uses the terms first, second, third, etc. to describe elements, components, regions, layers, and/or sections, it should be understood that such elements, components, regions, layers, and/or sections should not be limited by such terms. These terms are only used to distinguish one element, component, region, layer and/or block from another element, component, region, layer and/or block. They do not imply or represent any previous ordinal number of the element, nor do they represent the arrangement order of one element and another element, or the order of manufacturing methods. Therefore, the first element, component, region, layer or block discussed below can also be referred to as the second element, component, region, layer or block without departing from the specific embodiments of the present invention.

The term “about” or “substantially” mentioned in the present invention usually means within 20% of a given value or range, such as within 10%, or within 5%, or within 3%, or within 2%, or within 1%, or within 0.5%. It should be noted that the quantity provided in the specification is approximate, that is, the meaning of “about” or “substantially” can still be implied without specifying “about” or “substantially”.

The terms “coupling” and “electrical connection” mentioned in the present invention include any direct and indirect means of electrical connection. For example, if the first component is described as being coupled to the second component, it means that the first component can be directly electrically connected to the second component, or indirectly electrically connected to the second component through other devices or connecting means.

Although the invention of the present invention is described below by specific embodiments, the inventive principles of the present invention can also be applied to other embodiments. In addition, in order not to obscure the spirit of the present invention, specific details are omitted, and the omitted details are within the knowledge of those with ordinary knowledge in the technical field.

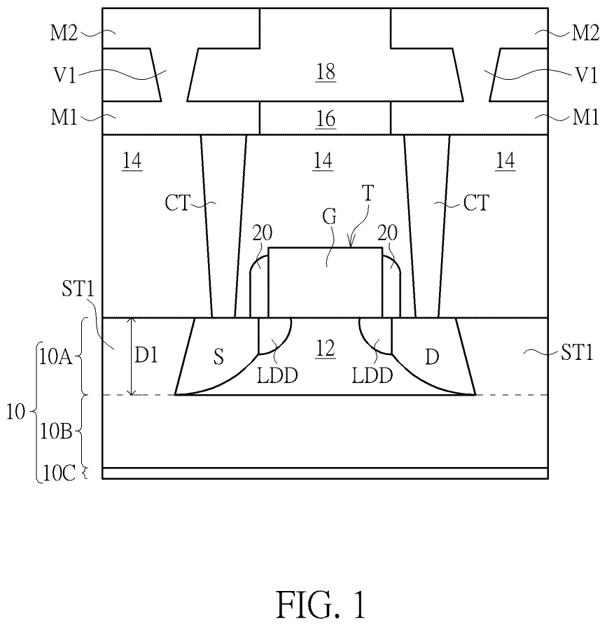

FIG. 1 depicts a cross-sectional schematic diagram of a semiconductor structure with a silicon-on-insulator (SOI) substrate according to an embodiment of the present invention. As shown in FIG. 1, a substrate 10 is provided, which is an SOI substrate comprising a silicon layer 10A located on top of an insulating layer. The material of the silicon layer 10A is silicon, while the material of the insulating layer, such as silicon oxide, silicon nitride, or silicon oxynitride. In this embodiment, the silicon layer 10A is positioned on an oxide layer 10B and a material layer 10C, wherein the material layer 10C can be silicon or silicon oxynitride, although the present invention is not limited to this. Next, a transistor T is formed above the silicon layer 10A, wherein the transistor T includes a gate G, a source region S, and a drain region D. Specifically, a well region 12, source region S, drain region D, and lightly doped drain (LDD) are formed in the silicon layer 10A by doping, and shallow trench isolations (STI) are formed on the outside of the source region S and the drain region D. In this embodiment, if the transistor is an N-type transistor, the source region S, drain region D, and lightly doped drain LDD are doped with N-type ions, while the well region 12 is doped with P-type ions. However, the present invention is not limited thereto. The material of the shallow trench isolation STI, such as silicon oxide, which is the same as that of the oxide layer 10B (the interface between the oxide layer 10B and the shallow trench isolation STI is indicated by dashed lines in FIG. 1).

Above the silicon layer 10A, there may be a multilayer structure containing multiple dielectric layers, the multiple components may comprises such as gate electrodes of transistors, contact structures, or wiring structures. Specifically, dielectric layers 14, 16, and 18 are located on the silicon layer 10A, with materials such as silicon oxide, silicon nitride, silicon oxynitride, ultra-low-k dielectric materials (ULK), low-k materials, or fluorosilicate glass (FSG). The gate G is surrounded by spacers 20 on both sides, and both the gate G and the spacers 20 are located within the dielectric layer 14. The gate G may be composed of polysilicon or metal, and there may be a gate dielectric layer (not shown) below the gate G. The spacers 20 may be made of materials such as silicon oxide, silicon nitride, or silicon oxynitride. Moreover, the dielectric layer 14 contains contact structures CT, electrically connecting the source region S and the drain region D, and then connecting to the metal layers M1, via studs V1, and metal layers M2 contained in the upper dielectric layers 16 and 18, which are used to connect the transistor T to other components, such as subsequent active or passive components, or other chips via hybrid bonding, etc.

It is worth noting that additional dielectric layers or metal layers may continue to be formed above the metal layer M2. The transistor structure and other components described in FIG. 1 are mostly known by those skilled in the art, therefore, the parts not detailed therein can be referred to known transistor structures or related components and are not repetitively described here.

According to the applicant's experiments, the structure and dimensions of silicon-on-insulator (SOI) substrates will affect the performance of semiconductor devices, such as transistors, with the thickness D1 of silicon layer 10A being a particularly important factor. Specifically, in some embodiments, the thickness of silicon layer 10A is about 750 angstroms. At this thickness, silicon layer 10A has a relatively large thickness. Because the gate G of transistor T is located above silicon layer 10A and silicon layer 10A has a larger thickness, there is sufficient space beneath gate G to store charge, thereby avoiding the occurrence of gate-induced drain leakage (GIDL) and affecting the electrical characteristics of the device. However, the larger thickness of silicon layer 10A also has corresponding drawbacks. For instance, as seen in the cross-sectional view, the interface area between the silicon layer 10A and the source region S, the drain region D, or the lightly doped drain (LDD) region is larger due to the greater thickness of silicon layer 10A, making it easier for charges to flow out from the aforementioned regions and resulting in lower gate capacitance (Coff) and higher energy consumption of the semiconductor device.

On the other hand, reducing the thickness of silicon layer 10A will also lead to other drawbacks. For example, if the thickness of silicon layer 10A is reduced to approximately 500 angstroms, although it may increase the gate capacitance (Coff) of the semiconductor device and reduce power consumption, however, the reduced thickness results in less space for charge storage beneath gate G, leading to issues such as gate-induced drain leakage (GIDL), reduced charge storage space, increased short-channel effects (SCE), higher off-state current (Ioff), and lower breakdown voltage.

In other words, whether the thickness of silicon layer 10A is larger (approximately 750 angstroms) or smaller (approximately 500 angstroms), there are corresponding drawbacks. The present invention proposes an improved silicon-on-insulator (SOI) substrate structure that combines the advantages of thicker and thinner silicon layers, and seeks to minimize the drawbacks associated with both embodiments, as detailed in the following paragraph.

In the following paragraphs, due to the focus on describing the structure of the silicon-on-insulator (SOI) substrate, only partial components are depicted in the corresponding diagrams, such as silicon layer 10A, oxide layer 10B, material layer 10C, source region S, drain region D, lightly doped drain (LDD) region, shallow trench isolation (STI), sidewall 20, and transistor T. Other components such as dielectric layers, contact structures, and metal layers are omitted and not depicted in the diagrams.

The following text will explain different embodiments of the silicon-on-insulator (SOI) structure and its fabrication method. For simplicity, the explanations mainly focus on the differences between the various embodiments, without repeating details that are common across them. Additionally, identical components in different embodiments are labeled with the same reference numbers for ease of comparison.

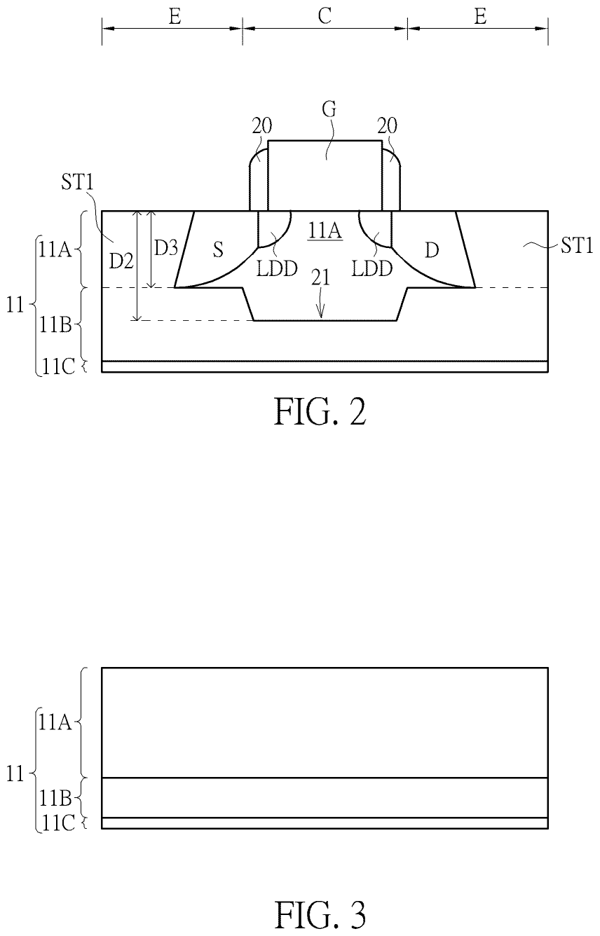

FIG. 2 illustrates a cross-sectional schematic of another embodiment of the semiconductor structure with a silicon-on-insulator (SOI) substrate, according to the present invention. As shown in FIG. 2, in this embodiment, a substrate 11 is provided, which is a silicon-on-insulator (SOI) substrate. From bottom to top, it sequentially includes a material layer 11C, an oxide layer 11B, and a silicon layer 11A. The silicon layer 11A, oxide layer 11B, and material layer 11C here have similar or identical features to those of silicon layer 10A, oxide layer 10B, and material layer 10C described in the first embodiment. However, there are slight differences in the shapes of some components as seen in the cross-sectional view, which will be described in detail in subsequent paragraphs.

The substrate 11 defines a central region C and two edge regions E, wherein the central region C is located between the two edge regions E. The gate G is positioned within the central region C, and the width of the central region C is approximately equal to the width of the gate G. However, it should be noted that the width of the central region C can be adjusted according to specific requirements.

In this embodiment, the oxide layer 11B within the central region C features a trench 21, positioned directly beneath the gate G and aligned with its position. Specifically, from a top view or a cross-sectional view, the defined area of the gate G overlaps with the area of the trench 21 by more than 90%. The silicon layer 11A is positioned on top of the oxide layer 11B and fills the trench 21. Consequently, the thickness of the silicon layer 11A is greater within the central region C compared to the edge regions E. Taking FIG. 2 as an example, within the central region C, the thickness of the silicon layer 11A equals the distance from the bottom surface of the gate G to the bottom surface of the trench 21 in the vertical direction, denoted as the height D2 in FIG. 2, which is approximately 750 angstroms in this embodiment, but not limited to. On the other hand, the thickness of the silicon layer 11A remains unchanged within the edge regions E, meaning the thickness of the silicon layer 11A within the edge regions E is less than that within the central region C. In FIG. 2, within the edge regions E, the thickness of the silicon layer 11A equals the distance from the bottom surface of the gate G to the top surface of the oxide layer 11B in the vertical direction, denoted as the height D3 in FIG. 2, which is approximately 500 angstroms in this embodiment, but not limited to.

In this embodiment, the semiconductor structure comprises a silicon-on-insulator (SOI) substrate with a specially shaped silicon layer 11A, wherein the thickness of the silicon layer 11A is greater within the central region C and smaller within the edge regions E. As a result, there is sufficient space beneath the gate G to store charges, providing the advantage of reducing gate-induced drain leakage (GIDL). Meanwhile, within the edge regions E, the interface area between the silicon layer and the source region S, drain region D, and lightly doped drain (LDD) region is smaller (due to the thickness of the silicon layer is also smaller), resulting in higher closure capacitance (Coff) and lower energy consumption. In other words, the semiconductor structure of this embodiment combines the advantages of the two embodiments shown in FIG. 1.

FIG. 3 to FIG. 5 illustrate a process flow of creating a semiconductor structure containing a silicon-on-insulator (SOI) substrate according to an embodiment of the present invention. As shown in FIG. 3, a substrate 11 is provided, comprising a stack structure of the material layer 11C, the oxide layer 11B, and the silicon layer 11A. The material characteristics of the material layer 11C, the oxide layer 11B, and the silicon layer 11A can be referenced from the various materials described in FIG. 2, thus not repeated here.

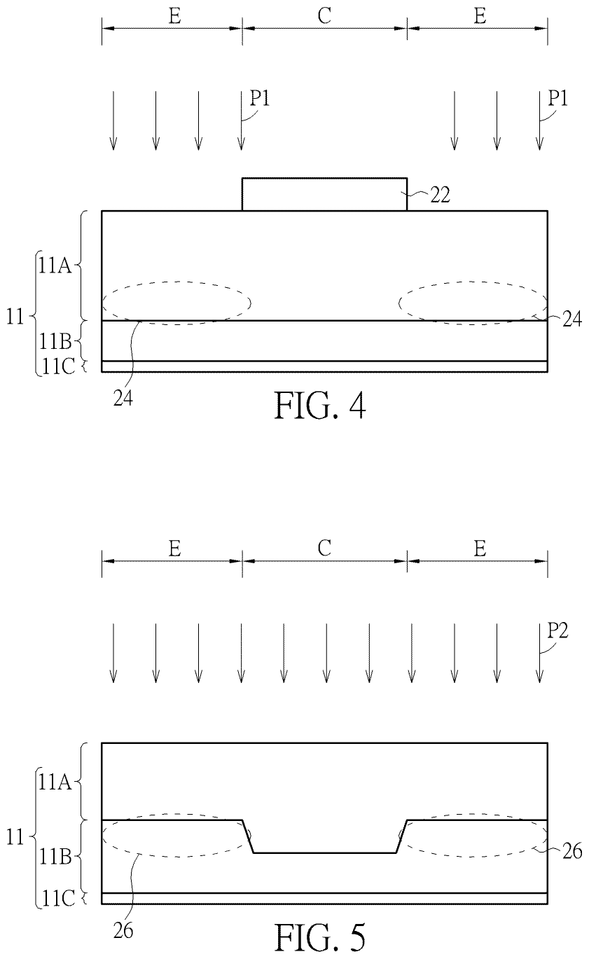

As shown in Fig. 4, a mask layer 22 is formed on the silicon layer 11A of the substrate 11, positioned within the central region C. Subsequently, an ion doping step P1 is performed, wherein oxygen ions (O⁺) are introduced into the silicon layer 11A. It is noteworthy that by controlling the parameters of the doping step P1, the depth of ion doping can be regulated. Specifically, oxygen ions can be doped into the region close to the oxide layer 11B within the edge regions E, forming a rich oxygen region 24. The rich oxygen region 24 contains a higher concentration of oxygen ions at its center, with a gradient decrease in oxygen ion concentration moving away from the center.

As depicted in FIG. 5, an annealing step P2 is then carried out, heating the temperature to approximately 1300 degrees Celsius, causing the oxygen ions within the rich oxygen region 24 to react with the silicon layer 11A, so as to form an oxide silicon layer 26. Because the silicon oxide layer 26 is adjacent to the lower oxide layer 11B, they can be combined with each other to form an integral silicon oxide layer. Following the annealing step P2, the thickness of the oxide layer 11B within the central region C of the substrate 11 remains unchanged, but within the edge regions E, the overall thickness of the oxide silicon layer (resulting from the combination of the oxide layer 11B and the oxide silicon layer 26) increases. Subsequent steps may involve the formation of other components such as the gate G, the source region S, the drain region D, the lightly doped drain (LDD) region, etc., to create a structure similar to that shown in FIG. 2. These steps are well-known techniques in the field and are not reiterated here. Therefore, the method described in this embodiment allows for the formation of a silicon-on-insulator (SOI) substrate 11 with a special shape, as shown in FIG. 2.

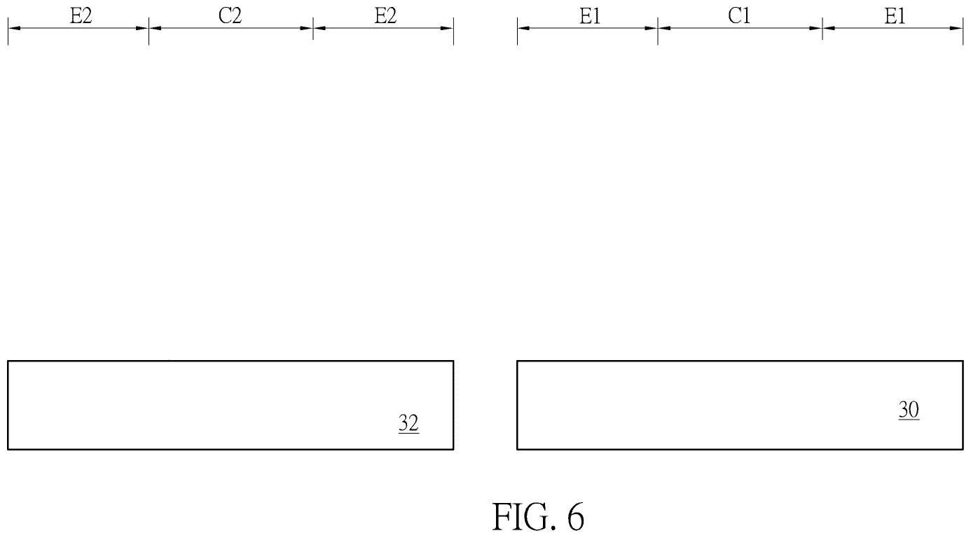

FIG. 3 to FIG. 5 illustrate the formation of a silicon-on-insulator (SOI) substrate 11 by doping oxygen ions into the silicon layer and performing annealing steps, as depicted in FIG. 2. Please refer to the FIG. 6 to FIG. 11 for another embodiment of the process flow for creating a semiconductor structure containing a silicon-on-insulator (SOI) substrate. As shown in FIG. 6, a material layer 30 and a silicon layer 32 are provided. The material layer 30 may comprises materials such as silicon or silicon nitride, but is not limited to these. As for the silicon layer 32, it may comprise a single-crystal silicon layer or a polycrystalline silicon layer, and the present invention is not limited thereto. Additionally, both the material layer 30 and the silicon layer 32 define central regions and edge regions. For clarity, the central region C1 and the edge region E1 are defined on the material layer 30, and the central region C2 and the edge region E2 are defined on the silicon layer 32. The definitions of the central region C1 and C2 and the edge regions E1 and E2 are the same as those described above, and will not be repeated here.

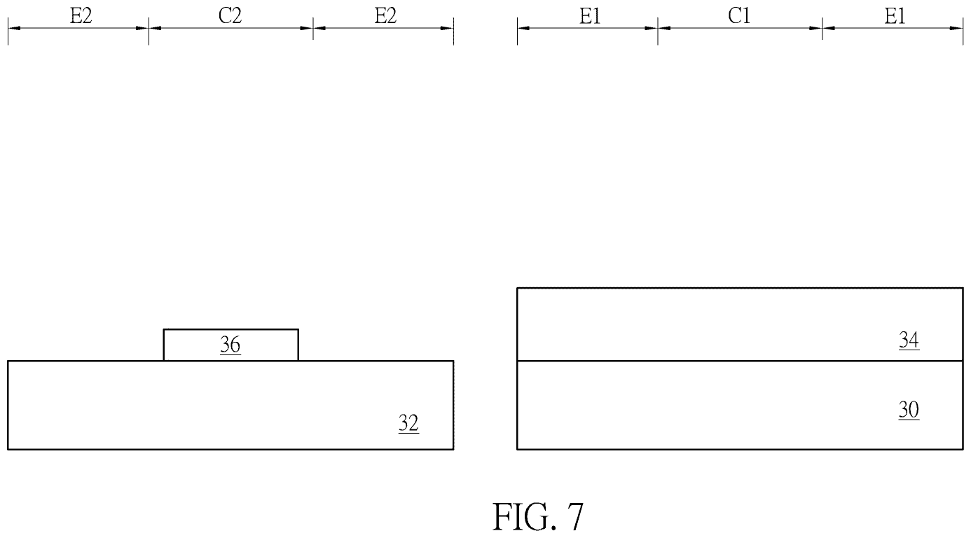

Continuing from FIG. 7, an oxide layer 34 is formed on the material layer 30, while a mask layer 36 is formed in the central region C2 of the silicon layer 32. The material of the oxide layer 34 may be silicon oxide, and the material of the mask layer 36 may be silicon oxide, silicon nitride, or silicon oxynitride, among others, but the present invention is not limited to these.

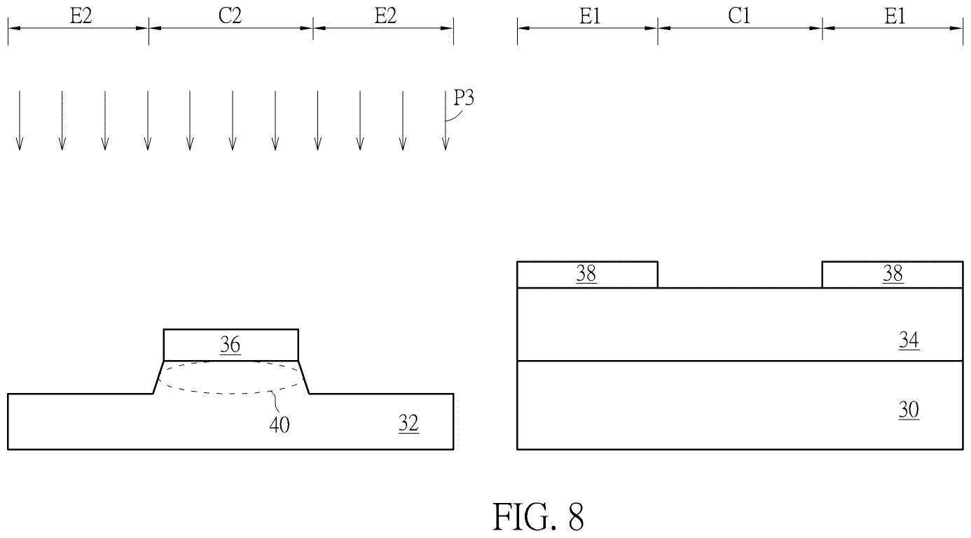

As shown in FIG. 8, a mask layer 38 is then formed within the edge region E1 on the oxide layer 34. The material of the mask layer 38 may be silicon oxide, silicon nitride, or silicon oxynitride, but the present invention is not limited to these. It is worth noting that in this embodiment, the mask layer 38 exposes the oxide layer 34 within the central region C1, in other words, there is no mask layer 38 formed within the central region C1.

Please continue referring to FIG. 8, wherein an etching step P3 is performed on the silicon layer 32. The etching step P3 may include, but is not limited to, dry etching or wet etching. Using the mask layer 36 as a mask, a portion of the silicon layer 32 within the edge region E2 is removed. Since the silicon layer 32 within the central region C2 is covered by the mask layer 36, it remains unaffected and retains its original height. After the etching step P3, a protrusion 40 appears on the top surface of the silicon layer 32.

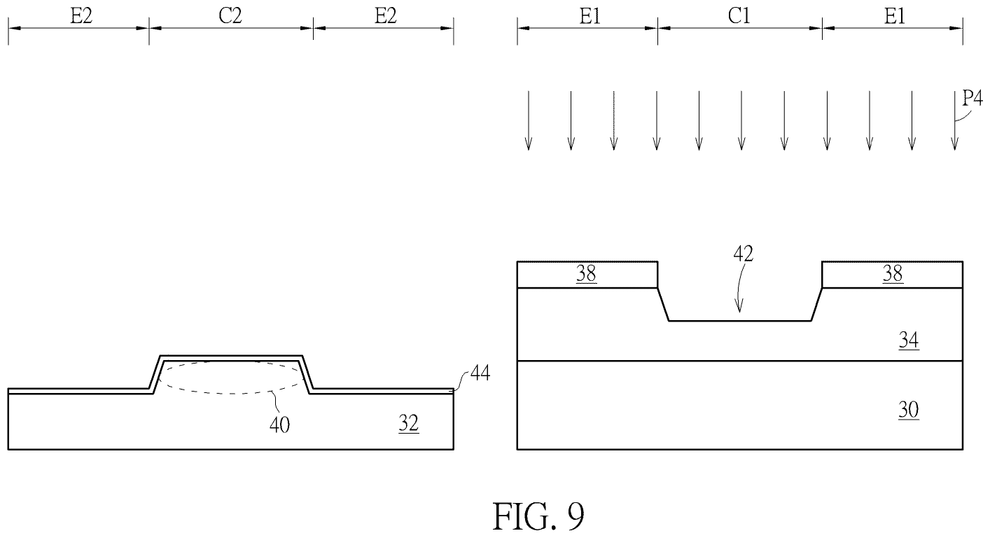

Next, as shown in FIG. 9, an etching step P4 is performed on the oxide layer 34. The etching step P4 may include, but is not limited to, dry etching or wet etching. Using the mask layer 38 as a mask, a portion of the oxide layer 34 within the central region C1 is removed. Since the oxide layer 34 within the edge region E2 is covered by the mask layer 38, it remains unaffected and retains its original height. After the etching step P4, a recessed portion 42 appears on the top surface of the oxide layer 34.

Continuing from FIG. 9, the mask layer 36 is removed. Then, an oxide layer 44 is formed on the top surface of the silicon layer 32 and the protrusion 40. The thickness of the oxide layer 44 is approximately within 100 angstroms, but it is not limited to this value. The oxide layer 44 can be formed by directly growing an oxide layer on the surface of the silicon layer 32 and the protrusion 40 through an oxidation step, or by depositing an oxide layer onto the surface of the silicon layer 32 and the protrusion 40 through a deposition step. Both methods are within the scope of the present invention.

It is worth noting that the recessed portion 42 formed within the oxide layer 34 in FIG. 9 corresponds to the protrusion 40 formed on the surface of the silicon layer 32 in FIG. 8. This means that in the following steps, the recessed portion 42 will combine with the protrusion 40. The purpose of forming the oxide layer 44 is to pre-form an oxide layer on the surface of the protrusion 40. Thus, during the subsequent step of combining the recessed portion 42 with the protrusion 40, the interface material for both will be silicon oxide, facilitating a better bond between the two components.

Furthermore, the formation of the oxide layer 44 serves another purpose, which is to adjust the width of the protrusion 40 and the oxide layer 44 to match the width of the recessed portion 42. Since the protrusion 40 and the recessed portion 42 will be combined in the subsequent steps to form a silicon-on-insulator substrate, adjusting the etching parameters in the previous etching steps P3 and P4 can ensure that the dimensions of the protrusion 40 and the recessed portion 42 match each other as closely as possible to avoid gaps at the interface. However, in practical processes, various errors may occur, resulting in incomplete correspondence between the dimensions of the protrusion 40 and the recessed portion 42. In such cases, the formation of the oxide layer 44 can cover the protrusion 40 and increase its size. Therefore, if the size of the protrusion 40 is smaller than that of the recessed portion 42, the formation of the oxide layer 44 can still be used to adjust the size, ensuring that gaps are less likely to occur at the interface during the subsequent bonding.

However, in other embodiments of the present invention, the step of forming the oxide layer 44 on the surface of the protrusion 40 may be omitted. In other words, the protrusion 40 may directly bond with the recessed portion 42 on the surface without the presence of the oxide layer 44. Such variations are also within the scope of the present invention.

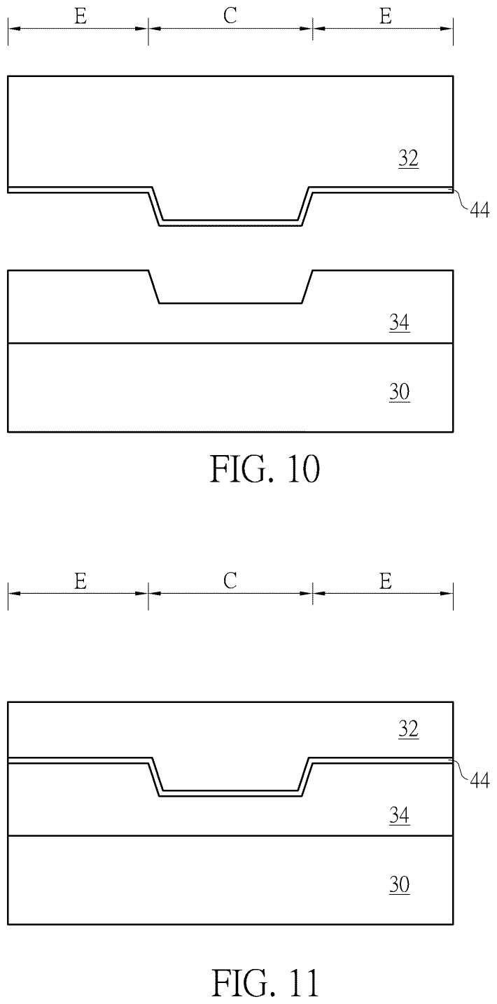

As shown in FIG. 10 and FIG. 11, after flipping the silicon layer 32 upside down, the protrusion 40 is aligned with the recessed portion 42 on the oxide layer 34 for bonding. At this point, the central region C and the edge region E can be redefined on the substrate. Subsequent grinding steps, such as a chemical mechanical polishing (CMP) to reduce the thickness of the silicon layer 32, can form the structure as shown in FIG. 11. The structure shown in FIG. 11 is similar to the silicon-on-insulator substrate 11 shown in FIG. 2 of previous embodiment, wherein the material layer 30 corresponds to the material layer 11C, the oxide layer 34 corresponds to the oxide layer 11B, and the silicon layer 32 corresponds to the silicon layer 11A. However, the processing method in this embodiment differs from the previous embodiment. Similarly, in subsequent steps, other elements such as the gate G, the source region S, the drain region D, the lightly doped drain (LDD) region, and other components of transistors can be formed to create a structure similar to that shown in FIG. 2. These steps are well-known to those skilled in the art and are not repeated here. Therefore, through the method described in this embodiment, a silicon-on-insulator substrate with a special shape similar to that shown in FIG. 2 can be formed.

Based on the above description and drawings, the present invention provides a semiconductor structure containing a silicon-on-insulator substrate 11 (refer to FIG. 2), comprising a material layer 11C defined with a central region C and two edge regions E, wherein the central region C is situated between the two edge regions E. An oxide layer 11B and a silicon layer 11A are stacked from bottom to top on the material layer, with the height D2 of the silicon layer 11A in the central region C being greater than the height D3 of the silicon layer in the two edge regions E.

In some embodiments of the present invention, the oxide layer 11B in the two edge regions E is flush at the top surface (as shown in FIG. 2, the top surfaces of the oxide layer 11B in the two edge regions E are flush with each other).

In some embodiments of the present invention, the bottom surface of the silicon layer 11A in the central region C is lower than the bottom surface of the silicon layer 11A in the two edge regions E (i.e., the bottom surface of the trench 21).

In some embodiments of the present invention, there is also a gate structure G located on the silicon layer 11A and positioned within the central region C.

In some embodiments of the present invention, there are further included a source region S and a drain region D, both located within the silicon layer 11A and respectively positioned within the two edge regions E.

In some embodiments of the present invention, there is also a shallow trench isolation (STI) located on the oxide layer 11B and positioned on both sides of the silicon layer 11A.

In some embodiments of the present invention, the top surface of the silicon layer 11A is flush with the top surface of the shallow trench isolation (STI).

The present invention also provides a method for manufacturing a semiconductor structure containing a silicon-on-insulator substrate (refer to FIG. 3 to FIG. 5), comprising the steps of providing a material layer 11C defined with a central region C and two edge regions E, wherein the central region C is situated between the two edge regions E; forming an oxide layer 11B and a silicon layer 11A stacked from bottom to top on the material layer; forming a mask layer 22 on the silicon layer 11A, with the mask layer 22 located within the central region C; and performing an oxygen ion implantation step P1, wherein oxygen ions penetrate through the silicon layer 11A.

In some embodiments of the present invention, the thickness of the oxide layer 11B in the central region C is less than the thickness of the oxide layer 11B in the two edge regions E (refer to FIG. 2 or FIG. 5).

In some embodiments of the present invention, after the oxygen ion implantation step, there is further included an annealing step P2, increasing the thickness of the oxide layer 11B in the two edge regions E (due to the combination of the oxide layer 11B with the oxide silicon layer 26, resulting in an overall increase in oxide layer thickness).

In some embodiments of the present invention, the bottom surface of the silicon layer 11A in the central region C is lower than the bottom surface of the silicon layer 11A in the two edge regions E.

In some embodiments of the present invention, there is further included forming a gate structure G on the silicon layer 11A, positioned within the central region C.

In some embodiments of the present invention, there is further included forming a source region S and a drain region D within the silicon layer 11A, each positioned within the two edge regions E.

The present invention further provides a method for manufacturing a semiconductor structure containing a silicon-on-insulator substrate (as shown in embodiments from FIG. 6 to FIG. 11), comprising the steps of providing a material layer 30 and a silicon layer 32, wherein both the material layer 30 and the silicon layer 32 are defined with a central region (C1/C2) and two edge regions (E1/E2), with the central region (C1 or C2) situated between the two edge regions (E1 or E2). An oxide layer 34 is formed on the material layer 30, and a first mask layer (mask layer 36) is formed on the central region C2 of the silicon layer 32. A first etching step P4 is performed on the oxide layer 34 to form a recessed portion 42 within the central region C1 of the oxide layer 34. A second etching step P3 is performed on the silicon layer 32 to form a protruding portion 40 within the central region C2 of the silicon layer 32. The silicon layer 32 is then flipped so that the recessed portion 42 on the oxide layer 34 and the protruding portion 40 on the silicon layer 32 can be mutually bonded.

In some embodiments of the present invention, after forming the protruding portion 40 within the central region C2 of the silicon layer 32, there is further included an oxidation step (such as the step of forming the oxide layer 44 shown in FIG. 9), to form a second oxide layer 44 on the surface of the protruding portion 40.

In some embodiments of the present invention, the step of forming the recessed portion 42 within the central region C1 of the oxide layer 34 further includes: forming two second mask layers 38 on the oxide layer 34 and within the edge regions E1, performing a second etching step P4 to remove a portion of the oxide layer 34 within the central region C1, and forming the recessed portion 42.

In some embodiments of the present invention, after the second oxide layer 44 is deposited on the protruding portion 40, the combined width of the protruding portion 40 and the second oxide layer 44 equals the width of the recessed portion 42.

In some embodiments of the present invention, before the oxidation step, the first mask layer 36 is removed.

In some embodiments of the present invention, there is further included a grinding step (as described in FIG. 11), to reduce the thickness of the silicon layer 32.

In some embodiments of the present invention, after the grinding step, the ratio between the height of the protruding portion 40 and the thickness of the silicon layer 32 ranges from 0.3 to 0.7 (as shown in FIG. 11, for example, with a silicon layer thickness of approximately 500 Å, the thickness of the protruding portion 40 is around 250 Å).

In summary, the present invention provides a semiconductor structure containing a silicon-on-insulator substrate with a special-shaped silicon-on-insulator substrate. The oxide layer in the central region has a recessed portion, resulting in a greater thickness of the silicon layer in the central portion while maintaining the thickness of the silicon layer in the edge region unchanged. As a result, the silicon layer thickness under the gate is increased, allowing for more space to accommodate stored charges, while the silicon layer thickness at the positions of the source/drain regions remains unchanged. Therefore, the present invention has several advantages: 1. Reducing interface capacitance; 2. Reducing bulk resistance; 3. Reducing the impact of gate-induced drain leakage (GIDL); 4. Compatibility with existing technology without requiring additional masks; 5. High off-state capacitance and reduced static power consumption; 6. Improved device quality.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor structure comprising a silicon-on-insulator substrate, comprising:
a material layer defined with a central region and two edge regions, wherein the central region is situated between the two edge regions;
an oxide layer and a silicon layer stacked from bottom to top on the material layer, wherein a thickness of the silicon layer in the central region greater than a thickness of the silicon layer in the two edge regions.

2. The semiconductor structure according to claim 1, wherein the oxide layer in the two edge regions has mutually aligned top surfaces.

3. The semiconductor structure according to claim 1, wherein a bottom surface of the silicon layer in the central region is lower than a bottom surface of the silicon layer in the two edge regions.

4. The semiconductor structure according to claim 1, further comprising a gate structure located on the silicon layer and situated within the central region.

5. The semiconductor structure according to claim 1, further comprising a source region and a drain region located within the silicon layer and respectively positioned within the two edge regions.

6. The semiconductor structure according to claim 1, further comprising shallow trench isolation located on the oxide layer and positioned on both sides of the silicon layer.

7. The semiconductor structure according to claim 6, wherein a top surface of the silicon layer is aligned with a top surface of the shallow trench isolation.

8. A method for manufacturing a semiconductor structure comprising a silicon-on-insulator substrate, comprising:
providing a material layer defined with a central region and two edge regions, wherein the central region is situated between the two edge regions;
forming an oxide layer and a silicon layer stacked from bottom to top on the material layer;
forming a mask layer on the silicon layer, wherein the mask layer is located within the central region; and
performing an ion implantation step to penetrate oxygen ions through the silicon layer.

9. The method for manufacturing a semiconductor structure according to claim 8, wherein a thickness of the oxide layer in the central region is less than a thickness of the oxide layer in the two edge regions.

10. The method for manufacturing a semiconductor structure according to claim 8, further comprising performing an annealing step after the ion implantation step to increase the thickness of the oxide layer within the two edge regions.

11. The method for manufacturing a semiconductor structure according to claim 8, wherein a bottom surface of the silicon layer in the central region is lower than a bottom surface of the silicon layer in the two edge regions.

12. The method for manufacturing a semiconductor structure according to claim 8, further comprising forming a gate structure on the silicon layer and positioned within the central region.

13. The method for manufacturing a semiconductor structure according to claim 8, further comprising forming a source region and a drain region in the silicon layer and respectively located within the two edge regions.

14. A method for manufacturing a semiconductor structure comprising a silicon-on-insulator substrate, comprising:
providing a material layer and a silicon layer, wherein the material layer and the silicon layer are respectively defined with a central region and two edge regions, and the central region is situated between the two edge regions;
forming an oxide layer on the material layer, and forming a first mask layer on the central region of the silicon layer;
performing a first etching step to form a recessed portion within the central region of the oxide layer;
performing a second etching step to form a protruding portion within the central region of the silicon layer;
flipping the silicon layer to make the recessed portion on the oxide layer to bond with the protruding portion on the silicon layer.

15. The method for manufacturing a semiconductor structure according to claim 14, further comprising performing an oxidation step after forming the protruding portion within the central region of the silicon layer to form a second oxide layer on the surface of the protruding portion.

16. The method for manufacturing a semiconductor structure according to claim 14, wherein the step of forming the recessed portion within the central region of the oxide layer further comprising:
forming two second mask layers on the oxide layer and within the edge regions;
performing the second etching step to remove a portion of the oxide layer within the central region, so as to form the recessed portion.

17. The method for manufacturing a semiconductor structure according to claim 15, wherein after the second oxide layer is formed on the protruding portion, a combined width of the protruding portion and the second oxide layer equals a width of the recessed portion.

18. The method for manufacturing a semiconductor structure according to claim 15, further comprising removing the first mask layer before performing the oxidation step.

19. The method for manufacturing a semiconductor structure according to claim 14, further comprising performing a grinding step to reduce the thickness of the silicon layer.

20. The method for manufacturing a semiconductor structure according to claim 19, wherein after the grinding step, the ratio of the height of the protruding portion to the thickness of the silicon layer is between 0.3 and 0.7.
